(19) United States
(12) Patent Application Publication
(10) Pub. No.: US 2013/0075714 A1
(43) Pub. Date: Mar. 28, 2013

(54) POLYMER, POLYMER COMPOSITION AND ORGANIC LIGHT-EMITTING DEVICE

(71) Applicants: Sheena Zuberi, Harrow (GB); Tania Zuberi, Harrow (GB)

(72) Inventors: Sheena Zuberi, Harrow (GB); Tania Zuberi, Harrow (GB)

(73) Assignee: SUMTOMO CHEMICAL COMPANY LIMITED, Chuo-ku, Tokyo (JP)

(21) Appl. No.: 13/698,049

(22) PCT Filed: May 12, 2011
(86) PCT No.: PCT/GB2011/000731

§ 371 Date: Nov. 14, 2012

(30) Foreign Application Priority Data
May 14, 2010 (GB) 1008091.9

(51) Int. Cl. H01L 51/00

(52) U.S. Cl. CPC H01L 51/0035; H01L 51/0038; H01L 51/0036
USPC 257/40; 252/500; 528/8; 528/25; 528/397; 528/396; 528/380; 528/391

(57) ABSTRACT

Light-emitting composition comprising a host polymer and a light emitting dopant wherein the host polymer comprises conjugating repeat units and non-conjugating repeat units in a backbone of the polymer and wherein: the conjugating repeat units provide at least one conjugation path between repeat units linked thereto; and the non-conjugating repeat units comprise an at least partially saturated ring having at least one ring atom that breaks any conjugation path between repeat units linked to the non-conjugating repeat unit such that a highest occupied molecular orbital level of the polymer is further from vacuum level by at least 0.1 eV and/or a lowest unoccupied molecular orbital level of the polymer is closer to vacuum level by at least 0.1 eV as compared to a polymer in which the non-conjugating repeat units are absent.

### SUMMARY OF THE INVENTION

This invention relates to charge transporting and light-emitting polymers and polymer compositions, in particular for use in organic light-emitting devices.

### BACKGROUND OF THE INVENTION

Electronic devices comprising active organic materials are attracting increasing attention for use in devices such as organic light emitting diodes, organic photoresponsive devices (in particular organic photovoltaic devices and organic photosensors), organic transistors and memory array devices. Devices comprising organic materials offer benefits such as low weight, low power consumption and flexibility. Moreover, use of soluble organic materials allows use of solution processing in device manufacture, for example inkjet printing or spin-coating.

With reference to FIG. 1, an organic light-emitting device (OLED) may comprise a substrate 1 carrying an anode 2, a cathode 4 and an organic light-emitting layer 3 between the anode and cathode comprising a light-emitting material.

During operation of the device, holes are injected into the device through the anode 2 and electrons are injected through the cathode 4. Holes in the highest occupied molecular orbital (HOMO) and electrons in the lowest unoccupied molecular orbital (LUMO) of the light-emitting material combine in the light-emitting layer to form an exciton that releases its energy as light.

Suitable light-emitting materials include small molecule, polymeric and dendrimeric materials. Suitable light-emitting polymers for use in layer 3 include poly(arylene vinylenes) such as poly(p-phenylene vinylenes) and polyarylenes such as polyfluorenes.

The light emitting layer may comprise a semiconducting host material and a light-emitting dopant wherein energy is transferred from the host material to the light-emitting dopant. For example, J. Appl. Phys. 65, 3610, 1989 discloses a host material doped with a fluorescent light-emitting dopant (that is, a light-emitting material in which light is emitted via decay of a singlet exciton) and Appl. Phys. Lett., 2000, 77, 904 discloses a host material doped with a phosphorescent light emitting dopant (that is, a light-emitting material in which light is emitted via decay of a triplet exciton).

A wide range of materials are known for use as hosts including “small molecule” materials such as tris-(8-hydroxyquinoline) aluminium (“A1q3”) and non-conjugated polymers such as polyvinylcarbazole (“PVK”).

Conjugated polymers (that is, polymers in which at least some adjacent repeat units in the polymer backbone are conjugated together) may also be used as host materials. Such conjugated polymers may possess numerous advantageous properties such as solubility, which allows the material to be deposited by solution coating or printing techniques, including processes such as spin-coating or inkjet printing, and high conductivity.

In order to function effectively as a host it is necessary for the relevant excited state energy level of the host material to be higher than that of the luminescent dopant that the host is to be used with (for example, the singlet excited state energy level S₁ for a fluorescent emitter and the triplet excited state energy level T₁ for a phosphorescent emitter). However, conjugation between adjacent repeat units of a conjugated polymer has the effect of lowering the excited state energy levels of the polymer as compared to the excited state energy levels of the monomers from which those repeat units are derived.

WO 2005/013386 discloses an organic light-emitting device comprising a host polymer material and a luminescent metal complex wherein the polymer material may comprise non-planar repeat units or partially or fully non-conjugated repeat units.

Li et al, Thin Solid Films 2006, Volume 515, Issue 4, pages 2686-2691 discloses a blue light-emitting polymer comprising fluorene repeat units and adamantane repeat units. The bulky adamantane unit is provided in order to reduce interactions between fluorene chains and to increase blue colour stability and current efficiency of devices containing the polymer.

Macromolecules 1998, 31, 1099-1103 discloses a blue light-emitting polymer comprising 9,9-dihexylfluorene repeat units linked through the 2- and 7-positions of the fluorene ring and 9,9-diphenylfluorene repeat units linked through the phenyl groups.

Polymer 2007 (48) p 7087 discloses poly(arylene ethers) containing multi-substituted pentaphenylene moiety.

### SUMMARY OF THE INVENTION

In a first aspect the invention provides a light-emitting composition comprising a host polymer and a light emitting dopant wherein the host polymer comprises conjugating repeat units and non-conjugating repeat units in a backbone of the polymer and wherein:

the conjugating repeat units provide at least one conjugation path between repeat units linked thereto; and

the non-conjugating repeat units comprise an at least partially saturated ring having at least one ring atom that breaks any conjugation path between repeat units linked to the non-conjugating repeat unit such that a highest occupied molecular orbital level of the polymer is further from vacuum level by at least 0.1 eV and/or a lowest unoccupied molecular orbital level of the polymer is closer to vacuum level by at least 0.1 eV as compared to a polymer in which the non-conjugating repeat units are absent.

Optionally, the at least one ring atom is a carbon atom.

Optionally, the at least partially saturated ring is carbocyclic, preferably a cycloalkane.

Optionally, the at least partially saturated ring is fused to at least one further ring.

Optionally, the at least one further ring is an aromatic ring.

Optionally, the at least one further ring is a non-aromatic ring.

Optionally, the non-conjugating repeat unit comprises adamantane.

Optionally, the light-emitting dopant is a fluorescent dopant

Optionally, the light-emitting dopant is a phosphorescent dopant

Optionally, the light-emitting dopant is blended with the host polymer.

Optionally, the light-emitting dopant is bound to the host polymer.

Optionally, the light-emitting dopant is present in the backbone of the polymer or a sidechain or endgroup of the polymer.

Optionally, the polymer comprises hole-transporting repeat units, optionally repeat units of formula (V):

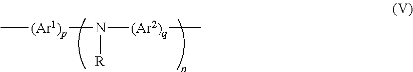

wherein Ar¹ and Ar² in each occurrence are independently selected from optionally substituted aryl or heteroaryl groups, n is greater than or equal to 1, preferably 1 or 2, R is H or a substituent, preferably a substituent, p and q are each independently 1, 2 or 3, and any of the aryl or heteroaryl groups of formula (V) may be linked by a direct bond or a divalent linking group.

Optionally, the polymer comprises electron-transporting repeat units, optionally repeat units of formula (II):

—(Ar¹)ᵣ-Het-(Ar²)ᵣ— (II)

wherein Ar¹ and Ar² are as described above; r is at least 1, preferably 1-3, Het represents an optionally substituted heteroaryl group with high electron affinity, and Ar¹, Ar² and Het independently in each occurrence are optionally substituted.

In a second aspect, the invention provides an organic light-emitting device comprising an anode, a cathode and a light-emitting layer between the anode and the cathode, the light-emitting layer comprising a light-emitting composition according to the first aspect.

In a third aspect the invention provides a polymer comprising conjugating repeat units, non-conjugating repeat units and amine repeat units in a backbone of the polymer wherein:

the conjugating repeat units provide at least one conjugation path between repeat units linked thereto;

the non-conjugating repeat units comprise an at least partially saturated ring comprising at least one ring atom that breaks any conjugation path between repeat units linked to the non-conjugating repeat unit such that a highest occupied molecular orbital level of the polymer is further from vacuum level by at least 0.1 eV and/or a lowest unoccupied molecular orbital level of the polymer is closer to vacuum level by at least 0.1 eV as compared to a polymer in which the non-conjugating repeat units are absent; and

the amine repeat units comprise repeat units of formula (V):

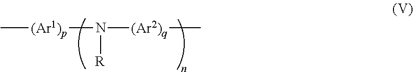

wherein Ar¹ and Ar² in each occurrence are independently selected from optionally substituted aryl or heteroaryl groups, n is greater than or equal to 1, preferably 1 or 2, R is H or a substituent, preferably a substituent, p and q are each independently 1, 2 or 3, and any of the aryl or heteroaryl groups of formula (V) may be linked by a direct bond or a divalent linking group.

In a fourth aspect the invention provides an organic light-emitting device comprising an anode, a cathode and at least one organic layer including a light-emitting layer between the anode and the cathode, at least one of the organic layers including the polymer according to the third aspect.

Optionally according to the fourth aspect, the polymer is a light-emitting polymer in the light-emitting layer of the device. In this case, optionally one of the organic layers is a hole-transporting layer and the polymer is a hole-transporting polymer in the hole transporting layer.

In a fifth aspect the invention provides use of a non-conjugating repeat unit to tune the HOMO-LUMO bandgap of a polymer comprising conjugating repeat units and the non-conjugating repeat units in a backbone of the polymer wherein:

the conjugating repeat units provide at least one conjugation path between repeat units linked thereto; and
the non-conjugating repeat units comprise an at least partially saturated ring having at least one ring atom that breaks any conjugation path between repeat units linked to the non-conjugating repeat unit, wherein said use causes the HOMO level of the polymer to move further from vacuum level by at least 0.1 eV and/or the LUMO level of the polymer to move closer to vacuum level by at least 0.1 eV as compared to a polymer in which the non-conjugating repeat units are absent.

In a sixth aspect the invention provides a method of tuning the bandgap of a polymer comprising conjugating repeat units and the non-conjugating repeat units in a backbone of the polymer wherein:

the conjugating repeat units provide at least one conjugation path between repeat units linked thereto; and
the non-conjugating repeat units comprise an at least partially saturated ring having at least one ring atom that breaks any conjugation path between repeat units linked to the non-conjugating repeat unit,
the method comprising the step of determining a minimum target bandgap of the polymer that is at least 0.1 eV larger than the bandgap of a polymer in which the non-conjugating repeat units are absent, and polymerising a polymerisation mixture comprising a first monomer comprising a non-conjugating unit and a second monomer comprising a conjugating unit, the ratio of the first and second monomers being selected so as to form a polymer having the minimum target bandgap.

In a seventh aspect the invention provides a light-emitting composition comprising a host polymer and a light emitting dopant wherein the host polymer comprises conjugating repeat units and non-conjugating repeat units in a backbone of the polymer and wherein:

the conjugating repeat units provide at least one conjugation path between repeat units linked thereto; and
the non-conjugating repeat units comprise an at least partially saturated ring having at least one ring atom that breaks any conjugation path between repeat units linked to the non-conjugating repeat unit, the at least one ring atom being a carbon atom.

The polymer described in the third, fifth, sixth and seventh aspects may optionally have any of the features of the polymer described with respect to the first aspect.

### DESCRIPTION OF THE DRAWINGS

The invention will now be described in more detail with reference to the drawings, wherein:

FIG. 1 illustrates an organic light-emitting device;

FIG. 2a illustrates a HOMO-LUMO gap for a comparative polymer; and

FIG. 2b illustrates a HOMO-LUMO gap for a polymer according to an embodiment of the invention.

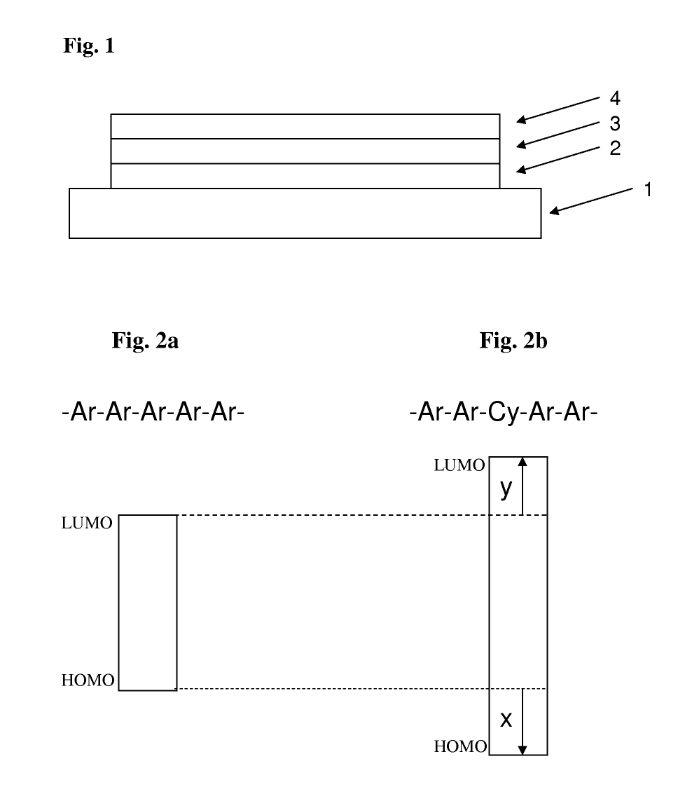

### DETAILED DESCRIPTION OF THE INVENTION

The polymer comprising non-conjugating cyclic spacer units may be used as a light-emitting material or as a host material for a light-emitting dopant in a light-emitting layer, a hole transporting material for use in a hole transporting layer between the anode and the light-emitting layer, or an electron transporting material for use in an electron transporting layer between the cathode and the light-emitting layer.

### Cyclic Non-Conjugating Units

Exemplary monomers suitable for forming cyclic non-conjugating repeat units of the polymer include monomers Ia, Ib, Ic and Id:

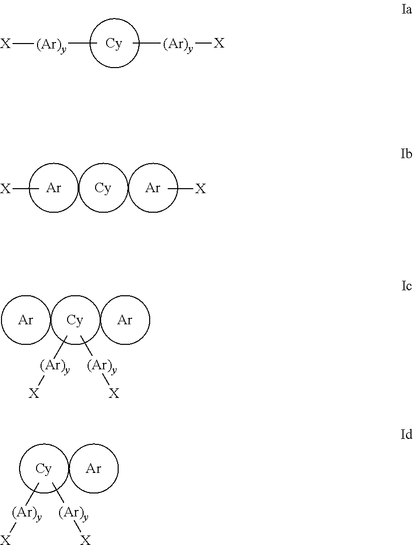

wherein:
Ar is an optionally substituted aryl or heteroaryl group, preferably optionally substituted phenyl;
y is 0 or an integer, preferably 0 or 1;
Cy is an at least partially saturated ring system that does not contain any aromatic rings and that has ring atoms that break any conjugation path between repeat units linked to the non-conjugating repeat unit, at least one of said ring atoms being a carbon atom; and
X is a leaving group capable of participating in a polymerisation reaction, in particular a leaving group for metal insertion polymerisation such as bromine, iodine, a boronic acid or ester or a sulfonic acid or ester.

Ar may be a monocyclic or fused aryl or heteroaryl group.

Cy may be a monocyclic, fused or spirocyclic ring system.

Specific monomers include monomers 1-28 below:

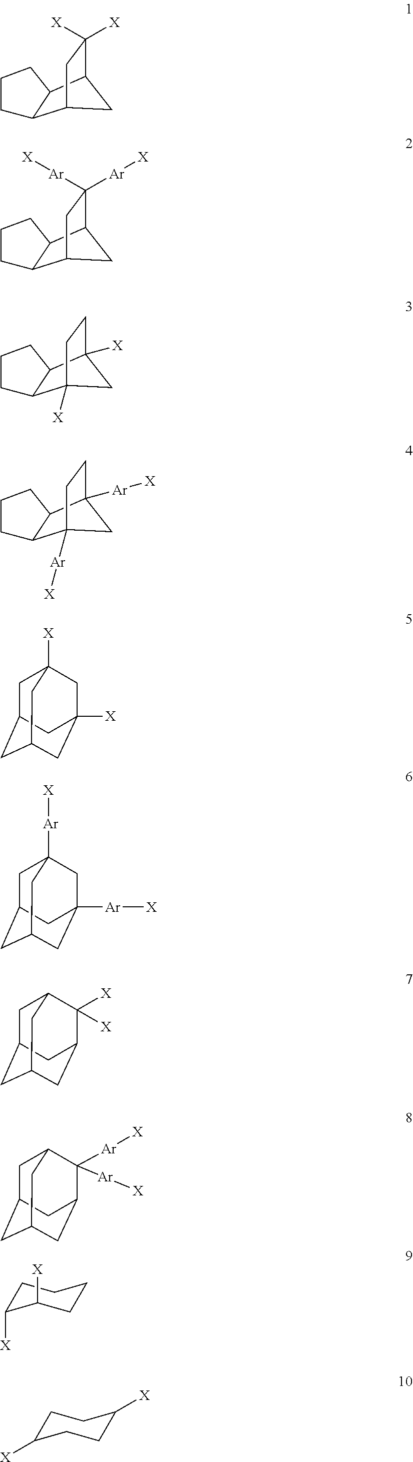

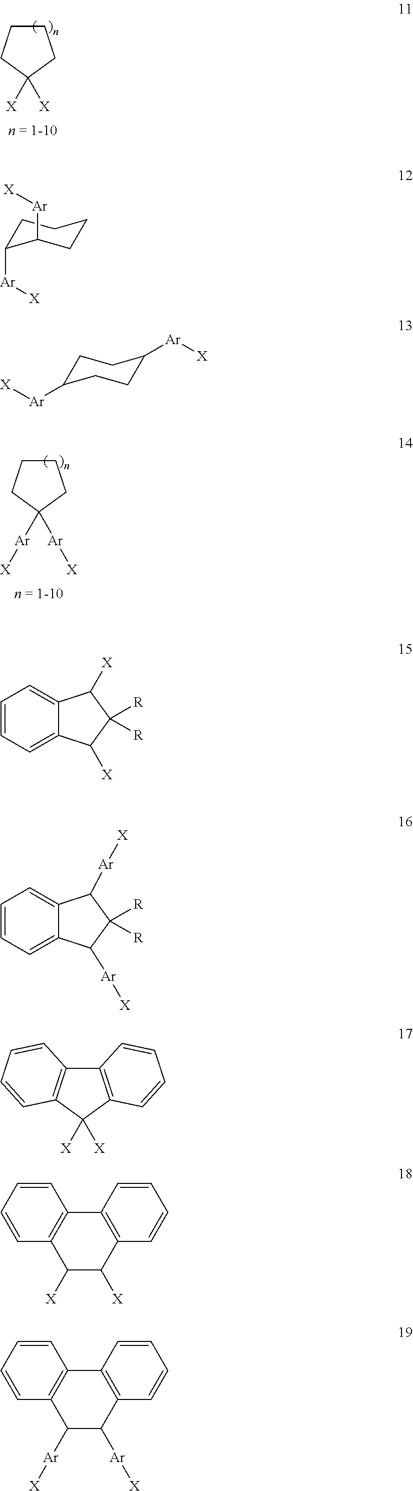

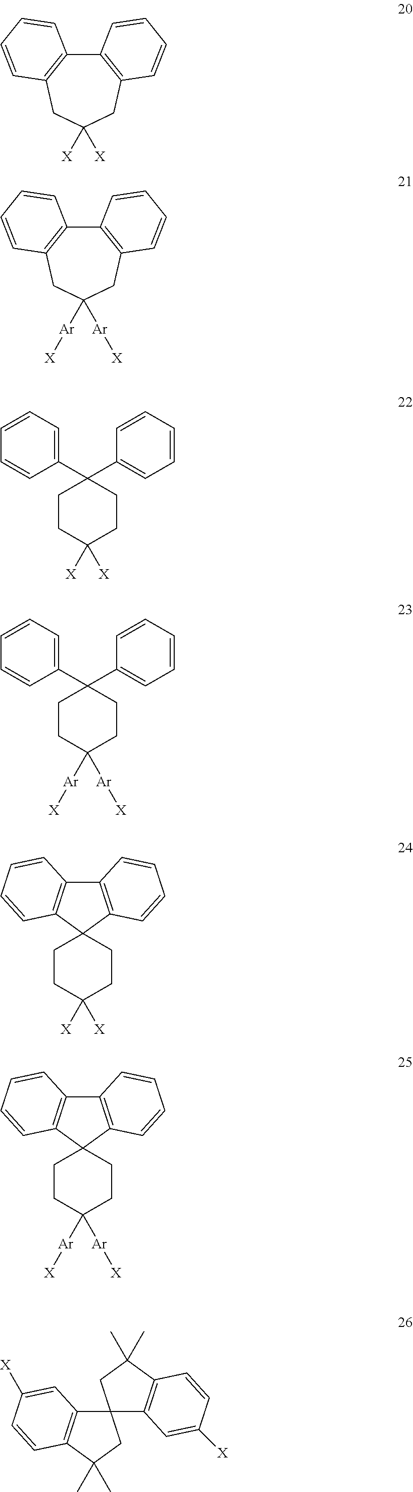

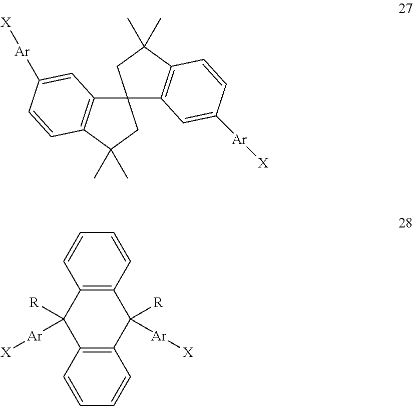

Examples of monomers having specific substituents X are illustrated below:

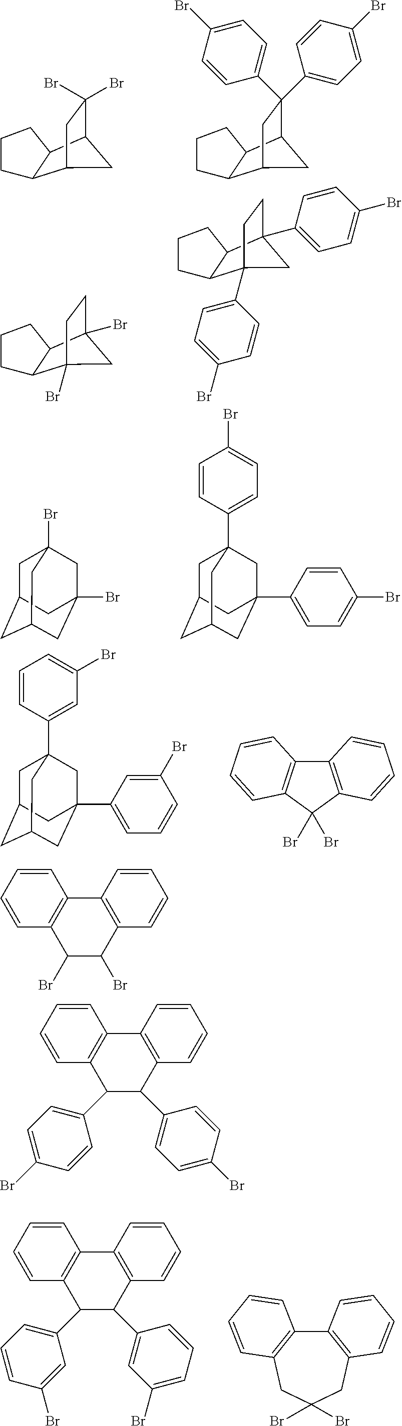

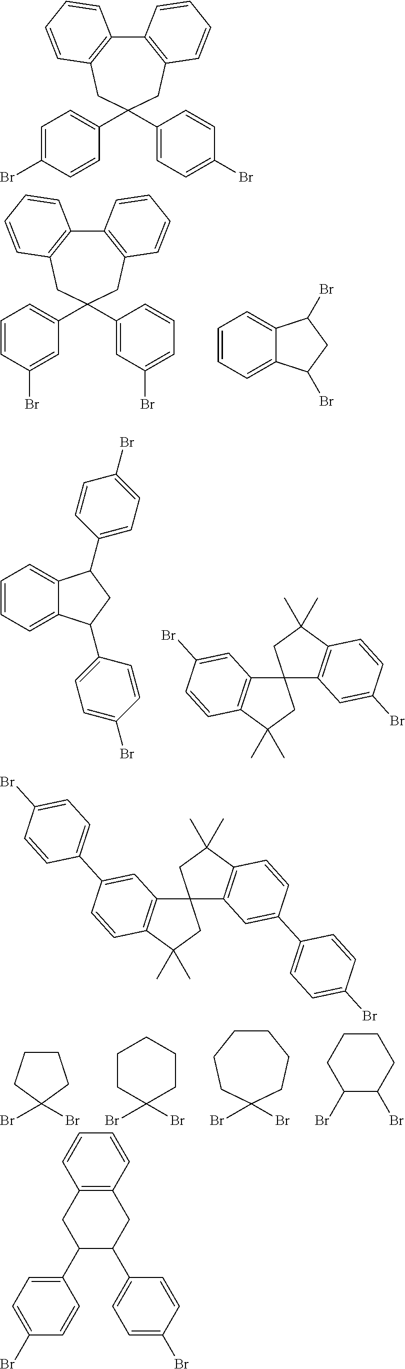

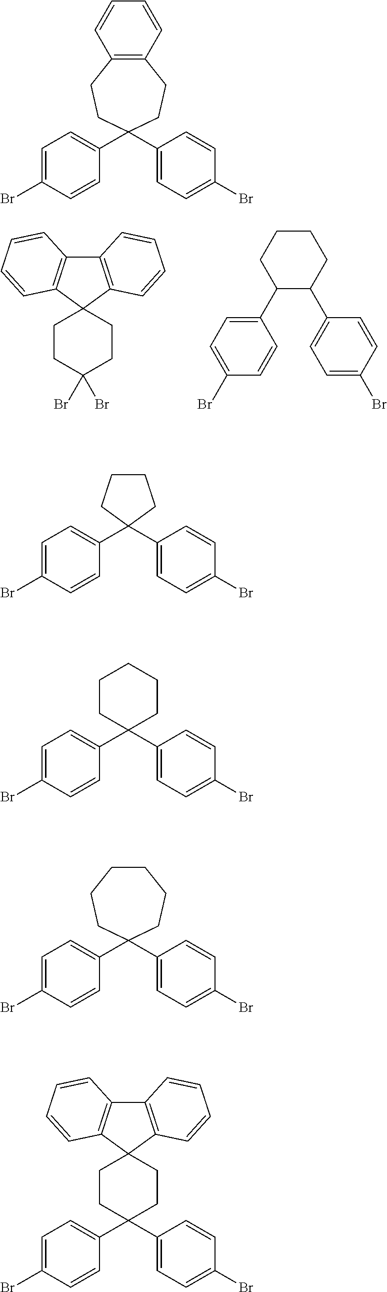

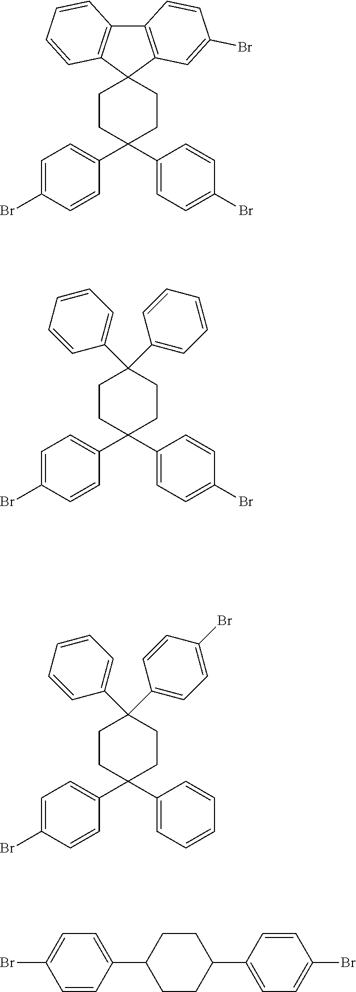 [SMILES: Brc1ccc(C2(c3ccc(Br)cc3)CCC3(CC2)c2ccccc2-c2ccc(Br)cc23)cc1 ; Brc1ccc(C2(c3ccc(Br)cc3)CCC(c3ccccc3)(c3ccccc3)CC2)cc1 ; Brc1ccc(C2(c3ccccc3)CCC(c3ccccc3)(c3ccc(Br)cc3)CC2)cc1 ; Brc1ccc(C2CCC(c3ccc(Br)cc3)CC2)cc1]

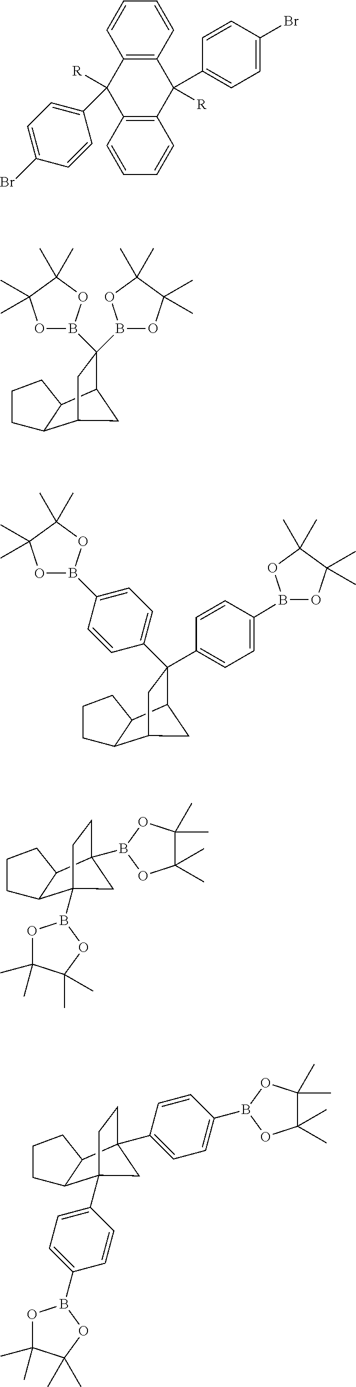

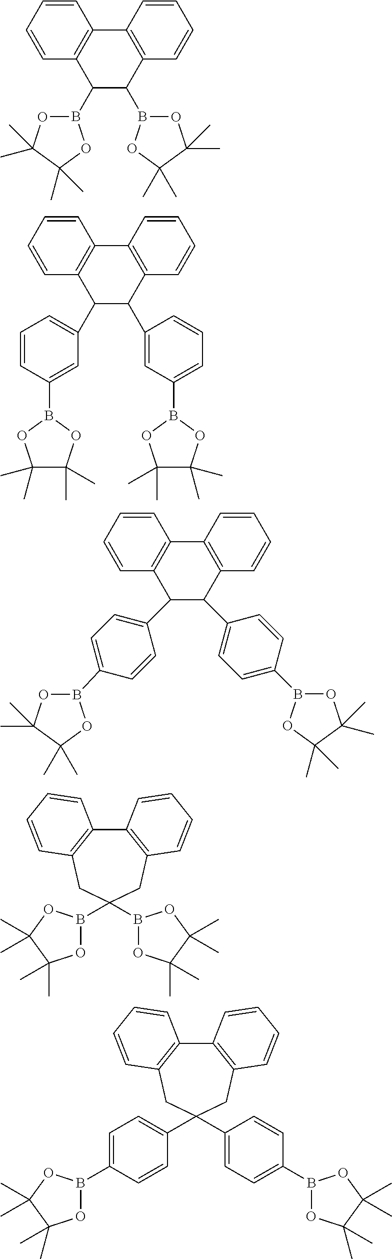

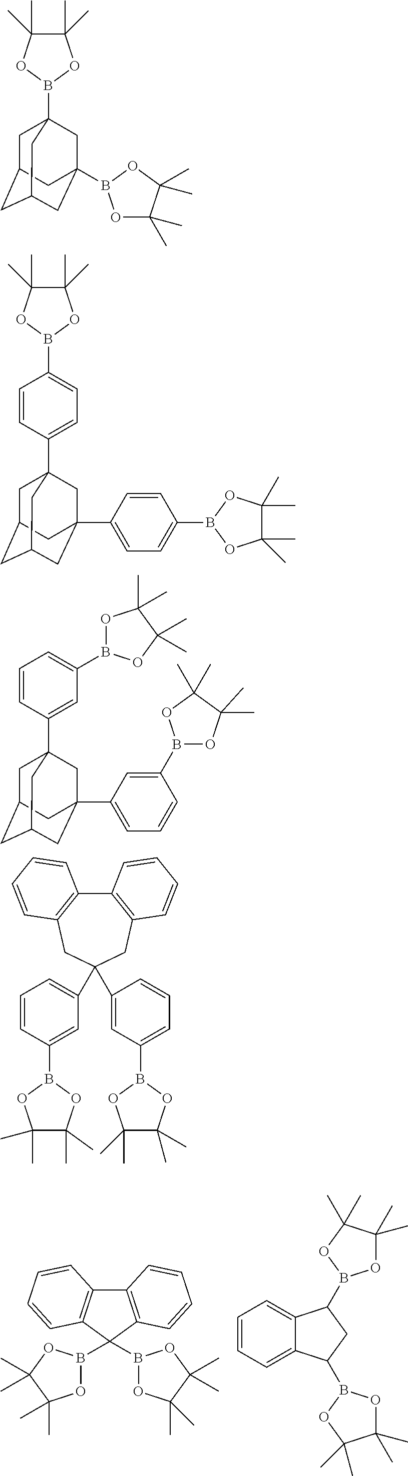

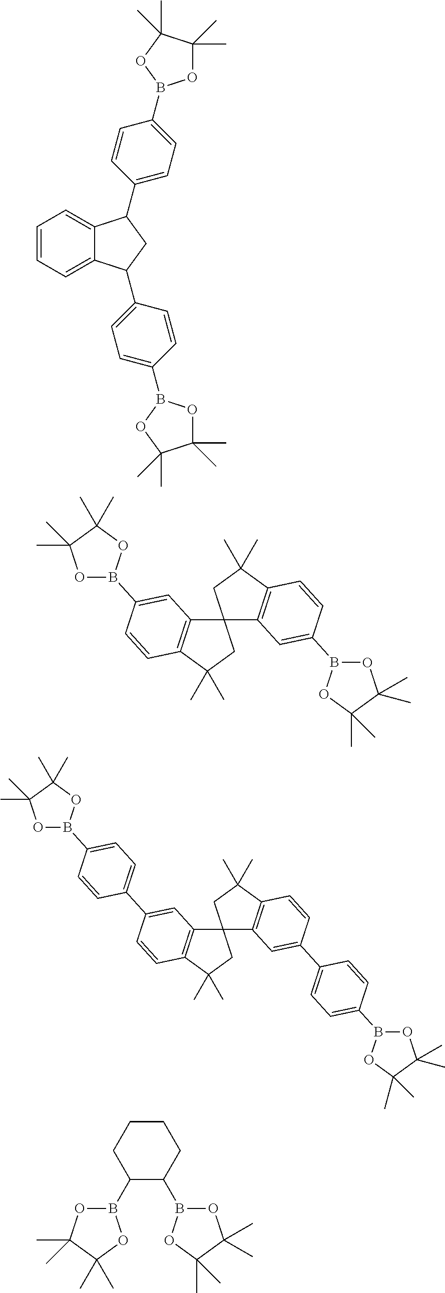

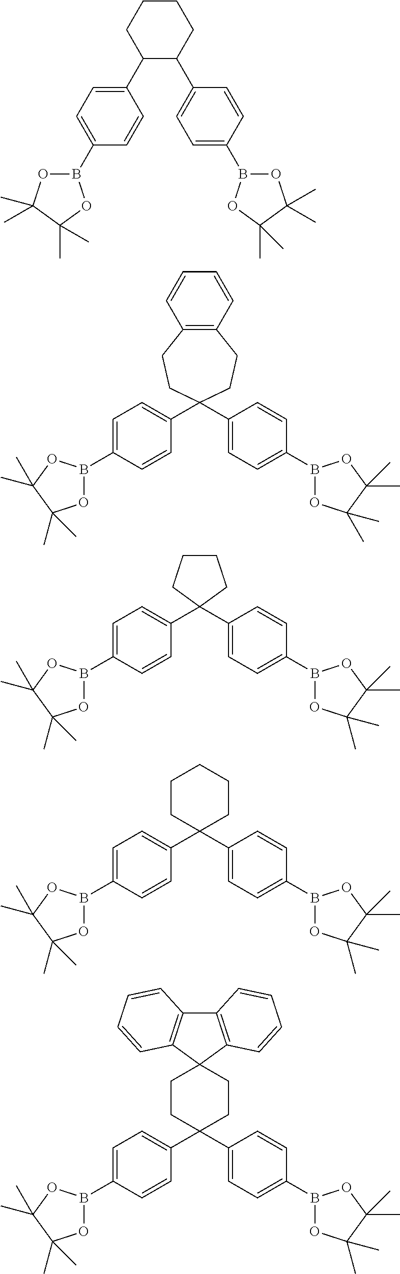

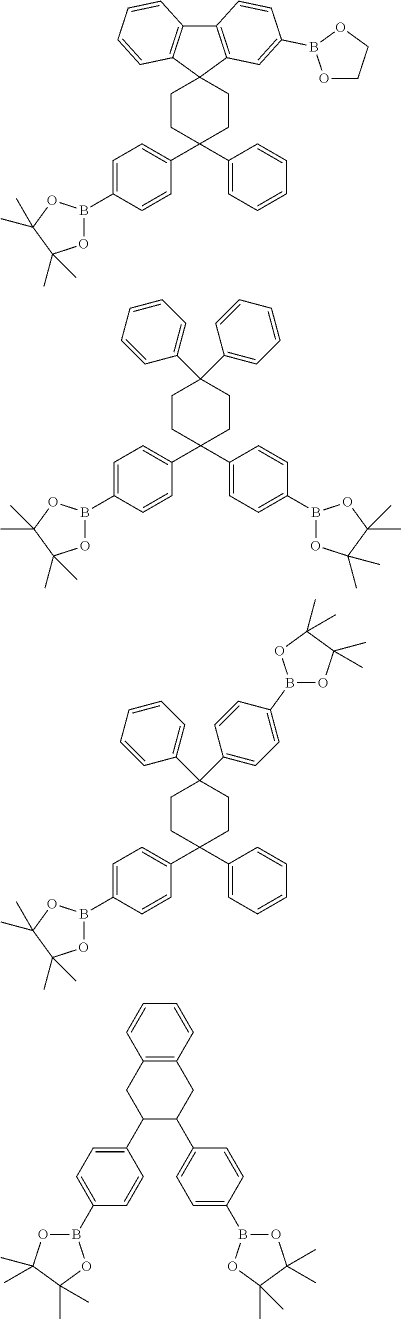

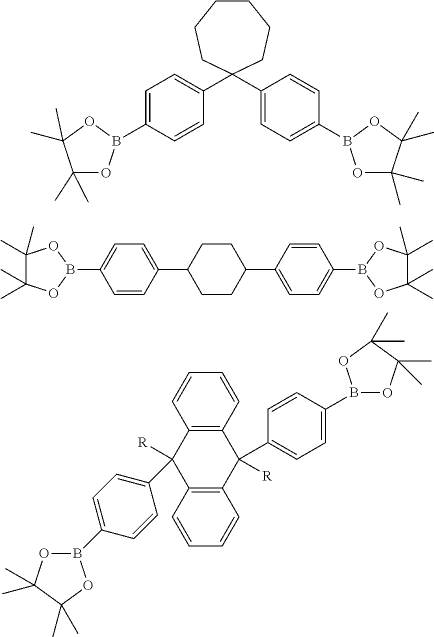

The dibromides and diesters may be synthesized by standard procedures known in the art. For example 1,3-dibromo-adamantane was reacted with 4-trimethylsilane bromobenzene under Friedel Crafts conditions to give the diaryl adamantly bromide.

Optionally, the polymer does not comprise a non-conjugating repeat unit derived from the following monomer:

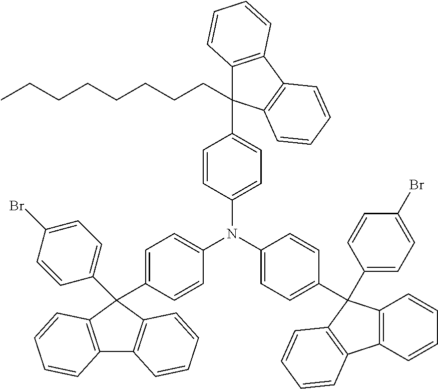

Upon polymerisation, one or more of the ring carbon atoms of the cyclic non-conjugating repeat units form a conjugation break along the backbone of the polymer between any adjacent conjugating repeat units; in other words, cyclic non-conjugating units do not provide a conjugation path between conjugated repeat units that they may be linked to (in particular, a path of alternating saturated and unsaturated bonds, for example alternating single and double bonds).

If all paths between adjacent repeat units pass through the same ring atom then that ring atom may provide a break in conjugation. Alternatively, if there is more than one path between adjacent repeat units, and the different paths do not all pass through the same ring atom, then different ring atoms may be provided in order that there is no conjugation path between adjacent repeat units.

The cyclic non-conjugating units may be saturated or may contain one or more unsaturated carbon-carbon bond provided that the units provide a break in conjugation along the backbone of the polymer as described above. For example, the cyclic non-conjugating repeat units may contain aromatic rings as illustrated above by units 15-28.

However, it will be appreciated that the cyclic non-conjugating unit itself preferably does not contain any extended conjugation, and if it contains more than one aromatic ring then it is preferable that there is a break in conjugation between two or more of the aromatic rings.

The polymer may comprise different cyclic non-conjugating repeat units.

Although specific X substitution positions are illustrated above, it will be appreciated that the X groups may be positioned anywhere on the monomer provided that the resulting cyclic non-conjugating unit does not provide a conjugation path between conjugated repeat units that it may be linked to.

The Ar and Cy groups of the cyclic non-conjugating repeat units may optionally be substituted with one or more substituents. Optional substituents include optionally substituted alkyl wherein one or more non-adjacent C atoms of the alkyl group may be replaced with O, S, substituted N, C═O and —COO—; and optionally substituted aryl or heteroaryl. In the case where the cyclic group is substituted with alkyl, optional substituents of the alkyl group include aryl, heteroaryl and F. Preferred substituents are alkyl.

### Conjugating Repeat Units

Exemplary conjugating repeat units include optionally substituted polyarylenes or polyheteroarylenes such as: optionally substituted polyfluorenes, in particular polymers comprising 2,7-linked fluorene repeat units; polyindenofluorenes, particularly 2,7-linked polyindenofluorenes; and polyphenylenes, particularly poly-1,4-phenylenes. Such polymers are disclosed in, for example, Adv. Mater. 2000 12(23) 1737-1750 and references therein. Exemplary substituents for these repeat units include alkyl, alkoxy, alklythio, dialkylamino, and optionally substituted aryl and heteroaryl groups.

Particularly preferred co-repeat units comprise optionally substituted fluorenes, such as repeat units of formula IV:

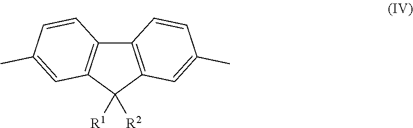

wherein R¹ and R² are independently H or a substituent and wherein R¹ and R² may be linked to form a ring.

R¹ and R² are optionally selected from the group consisting of hydrogen; optionally substituted alkyl wherein one or more non-adjacent C atoms of the alkyl group may be replaced with O, S, substituted N, C═O and —COO—; and optionally substituted —(Ar³)ᵣ wherein Ar³ in each occurrence is independently selected from aryl or heteroaryl and r in each occurrence is independently at least 1, optionally 1, 2 or 3.

In the case where R¹ or R² comprises alkyl, optional substituents of the alkyl group include F, CN, nitro, and aryl or heteroaryl optionally substituted with one or more groups R⁴ wherein each R⁴ is independently alkyl in which one or more non-adjacent C atoms may be replaced with O, S, substituted N, C═O and —COO— and one or more H atoms of the alkyl group may be replaced with F.

In the case where R¹ or R² comprises aryl or heteroaryl, each aryl or heteroaryl group may independently be substituted. Preferred optional substituents for the aryl or heteroaryl groups include one or more substituents R³ consisting of:
alkyl wherein one or more non-adjacent C atoms may be replaced with O, S, substituted N, C═O and —COO— and one or more H atoms of the alkyl group may be replaced with F or aryl or heteroaryl optionally substituted with one or more groups R⁴,
aryl or heteroaryl optionally substituted with one or more groups R⁴,
NR52, OR5, SR5, and
fluorine, nitro and cyano;
wherein each R⁵ is independently selected from the group consisting of alkyl and aryl or heteroaryl optionally substituted with one or more alkyl groups.

Where present, substituted N in repeat units of formula (IV) may independently in each occurrence be NR⁵ or NR⁶ wherein R⁶ is alkyl or optionally substituted aryl or heteroaryl. Optional substituents for aryl or heteroaryl groups R⁶ may be selected from R⁴ or R⁵.

Optional substituents for the fluorene unit, other than substituents R¹ and R², are preferably selected from the group consisting of alkyl wherein one or more non-adjacent C atoms may be replaced with O, S, substituted N, C═O and —COO—, optionally substituted aryl, optionally substituted heteroaryl, fluorine, cyano and nitro.

In one preferred arrangement, at least one of R¹ and R² comprises an optionally substituted C₁-C₂₀ alkyl or an optionally substituted aryl group, in particular phenyl substituted with one or more C₁₋₂₀ alkyl groups.

Conjugating repeat units may provide electron-transporting functionality. Typical electron transport materials provide the polymer with a high electron affinity (3 eV or higher, preferably 3.2 eV or higher) and high ionisation potential (5.8 eV or higher) Suitable electron transport groups include groups disclosed in, for example, Shirota and Kageyama, Chem. Rev. 2007, 107, 953-1010.

Conjugating electron transport groups include groups comprising formula (II):

—(Ar¹)ᵣ-Het-(Ar²)ᵣ— (II)

wherein Ar¹ and Ar² are as defined above; r is at least 1, preferably 1-3, and Het represents an optionally substituted heteroaryl group with high electron affinity. Optional substituents for Het are as described with respect to R above. In the case where Het is substituted with an aryl or heteroaryl group, this may be a group —(Ar³)ᵣ as described above.

Suitable heteroaryls with high electron affinity include triazine, pyrimidine, oxadiazole, pyridine, triazole, triarylborane, sulfoxide and silole Exemplary electron-transporting groups include the following:

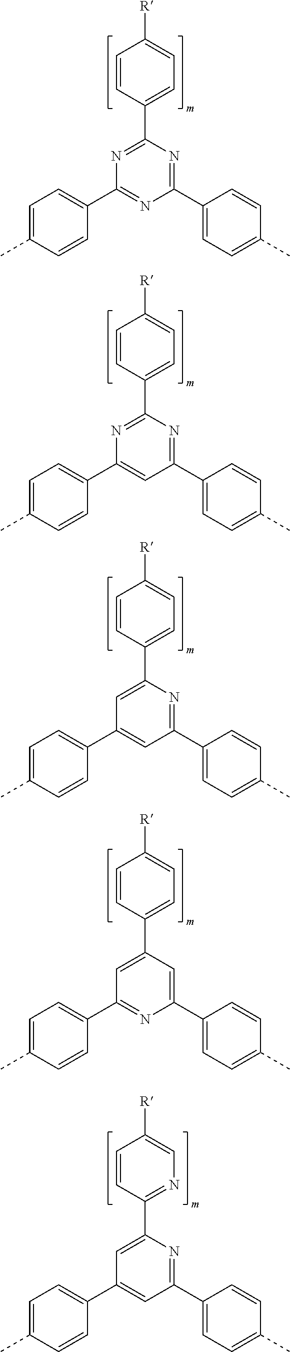

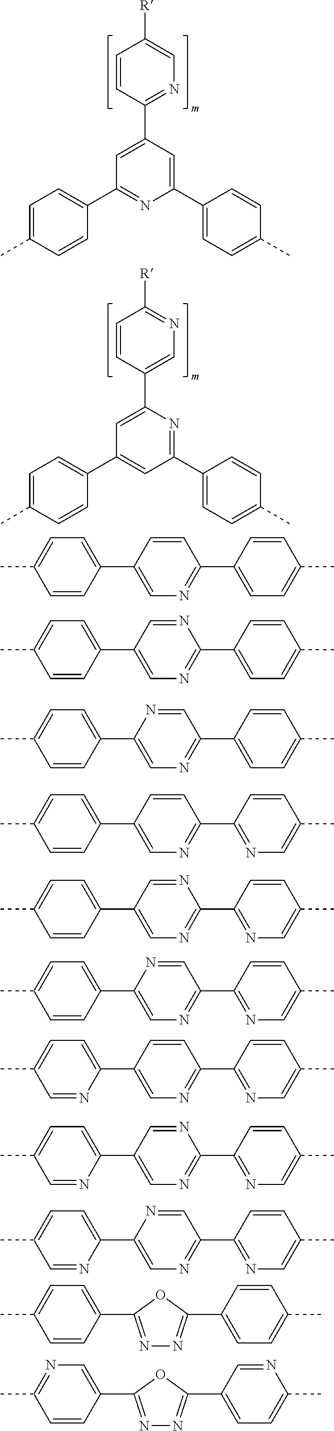

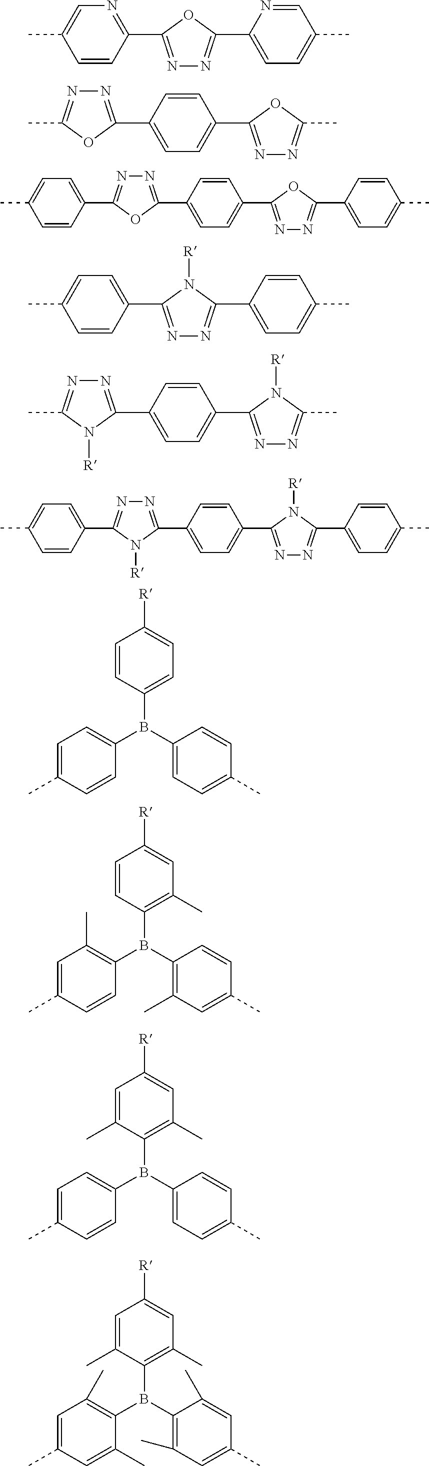

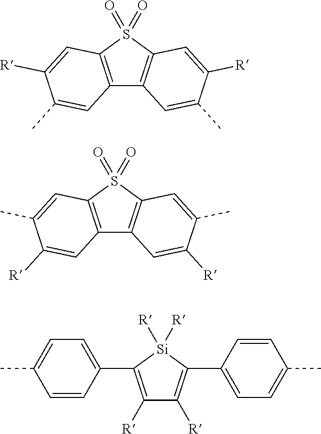

wherein R′ is as described above.

Other suitable electron transport materials include optionally substituted ketones, diarylsulfoxides, and phosphine oxides,

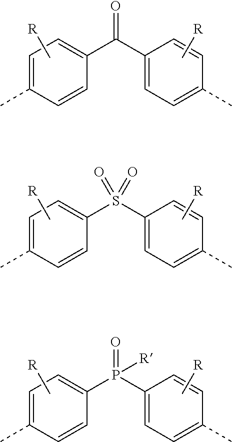

wherein each R is H or a substituent, preferably H or alkyl or aryl.

Further repeat units suitable for inclusion in the polymer for use as a host material or as a light-emitting material include arylamine repeat units, for example repeat units of formula (V):

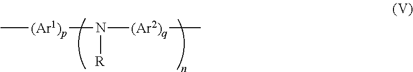

wherein Ar¹ and Ar² in each occurrence are independently selected from optionally substituted aryl or heteroaryl groups, n is greater than or equal to 1, preferably 1 or 2, R is H or a substituent, preferably a substituent, and p and q are each independently 1, 2 or 3.

R is preferably alkyl or —(Ar³)ᵣ, wherein Ar³ and r are as described above.

Any of Ar¹, Ar² and Ar³ may independently be substituted with one or more substituents. Preferred substituents are selected from R³ as described above.

Any of the aryl or heteroaryl groups in the repeat unit of Formula (V) may be linked by a direct bond or a divalent linking atom or group. Preferred divalent linking atoms and groups include O, S and substituted N.

Where present, substituted N or of the divalent linking group may independently in each occurrence be NR⁶.

In one preferred arrangement, R is Ar³ and each of Ar¹, Ar² and Ar³ are independently and optionally substituted with one or more C₁₋₂₀ alkyl groups.

Preferred units satisfying Formula 1 include units of Formulae 1-3:

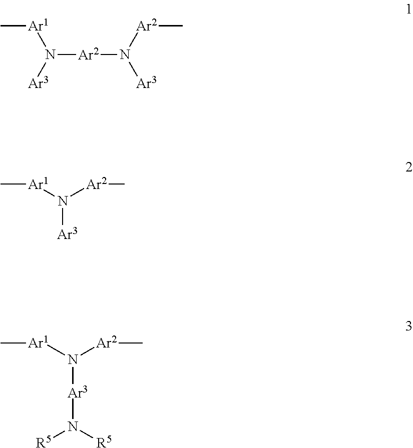

wherein Ar¹ and Ar² are as defined above; and Ar³ is optionally substituted aryl or heteroaryl. Where present, optional substituents for Ar³ may be as described above with respect to formula (V).

In another preferred arrangement, aryl or heteroaryl groups of formula (V) are phenyl, each phenyl group being optionally substituted with one or more alkyl groups.

In another preferred arrangement, Ar¹, Ar² and Ar³ are phenyl, each of which may be substituted with one or more C₁₋₂₀ alkyl groups, and r=1.

In yet another preferred arrangement, Ar¹, Ar² and Ar³ are phenyl, each of which may be substituted with one or more C₁₋₂₀ alkyl groups, r=1 and Ar¹ and Ar² are linked by an O or S atom.

Arylamine repeat units may provide hole transporting and/or light-emitting functionality, and the quantity of arylamine repeat units may be selected according to the layer in which the arylamine repeat unit is to be used. For example, when used in a light-emissive layer the proportion of arylamine repeat units may be up to about 30 mol % of the total number of polymer repeat units, whereas the proportion may be higher if the polymer is for use in a hole transporting layer.

One or more repeat units of the polymer may be substituted with a crosslinkable group, in particular if, during device manufacture, a device layer is to be deposited from solution onto the layer containing the polymer (for example if the polymer is provided in a hole transporting layer and if a light-emitting layer is deposited onto the hole transporting layer from a solution in a solvent).

Exemplary crosslinkable groups include groups comprising a double bond such as groups containing a vinyl or acrylate moiety or groups comprising a cyclobutane moiety such as benzocyclobutane. The polymer may be crosslinked following its deposition by crosslinking of the crosslinkable group.

The non-conjugating repeat units, conjugating repeat units and further repeat units illustrated above all have only two linking positions which when polymerised together form linear polymers. However, it will be appreciated that any of these repeat units may be provided with more than two linking positions, for example in order to form starburst polymers. The maximum possible number of linking positions of a monomer will correspond to the number of polymerisable leaving groups that it is substituted with.

### Polymer Synthesis

Preferred methods for preparation of the polymer comprise a “metal insertion” wherein the metal atom of a metal complex catalyst is inserted between an aryl or heteroaryl group and a leaving group of a monomer. Exemplary metal insertion methods are Suzuki polymerisation as described in, for example, WO 00/53656 and Yamamoto polymerisation as described in, for example, T. Yamamoto, “Electrically Conducting And Thermally Stable π-Conjugated Poly(arylene)s Prepared by Organometallic Processes”, Progress in Polymer Science 1993, 17, 1153-1205. In the case of Yamamoto polymerisation, a nickel complex catalyst is used; in the case of Suzuki polymerisation, a palladium complex catalyst is used.

For example, in the synthesis of a linear polymer by Yamamoto polymerisation, a monomer having two reactive halogen groups is used. Similarly, according to the method of Suzuki polymerisation, at least one reactive group is a boron derivative group such as a boronic acid or boronic ester and the other reactive group is a halogen. Preferred halogens are chlorine, bromine and iodine, most preferably bromine.

It will therefore be appreciated that repeat units illustrated throughout this application may be derived from a monomer carrying suitable leaving groups Likewise, an end group or side group may be bound to the polymer by reaction of a suitable leaving group.

Suzuki polymerisation may be used to prepare regioregular, block and random copolymers. In particular, homopolymers or random copolymers may be prepared when one reactive group is a halogen and the other reactive group is a boron derivative group. Alternatively, block or regioregular copolymers may be prepared when both reactive groups of a first monomer are boron and both reactive groups of a second monomer are halogen.

As alternatives to halides, other leaving groups capable of participating in metal insertion include sulfonic acids and sulfonic acid esters such as tosylate, mesylate and triflate.

### Polymer Tuning

The proportion of non-conjugating repeat units, conjugating repeat units and further repeat units may be selected in order to tune one or more properties of the polymer including such as colour of emission or singlet or triplet excited state energy level. In particular, increasing the proportion of non-conjugating repeat units in the polymer will reduce the average length of conjugating repeat units chains and therefore increase the excited state energy level of the polymer. This is illustrated in FIGS. 2a and 2b, wherein introduction of a cyclic non-conjugating group Cy into a polymer chain comprising conjugated aromatic or heteroaromatic groups Ar has the effect of breaking conjugation along the polymer chain and thereby increasing the HOMO-LUMO bandgap of the polymer by deepening the HOMO level (i.e. moving the HOMO level further from vacuum level) by at least 0.1 eV (illustrated by change x in FIG. 2b) and/or by moving the LUMO level closer to vacuum level by at least 0.1 eV (illustrated by change y in FIG. 2b). HOMO and LUMO levels may be measured by cyclic voltammetry.

On the other hand, it is preferable to keep the conductivity of the polymer as high as possible. Accordingly, a suitable quantity of non-conjugating repeat units in the polymer as a percentage of the total number of repeat units in the polymer may be in the range of 5-30 mol % and most preferably 5-20%.

### Light-Emitting Dopants

Materials that may be used as fluorescent or phosphorescent light-emitting dopants in the case where the polymer is used as a host material include metal complexes comprising optionally substituted complexes of formula (III):

ML¹_{q}L²ᵣL³ₛ (III)

wherein M is a metal; each of L¹, L² and L³ is a coordinating group; q is an integer; r and s are each independently 0 or an integer; and the sum of (a. q)+(b. r)+(c.s.) is equal to the number of coordination sites available on M, wherein a is the number of coordination sites on L¹, b is the number of coordination sites on L² and c is the number of coordination sites on L³.

Heavy elements M induce strong spin-orbit coupling to allow rapid intersystem crossing and emission from triplet or higher states (phosphorescence). Suitable heavy metals M include:
lanthanide metals such as cerium, samarium, europium, terbium, dysprosium, thulium, erbium and neodymium; and
d-block metals, in particular those in rows 2 and 3 i.e. elements 39 to 48 and 72 to 80, in particular ruthenium, rhodium, palladium, rhenium, osmium, iridium, platinum and gold. Iridium are particularly preferred.

Suitable coordinating groups for the f-block metals include oxygen or nitrogen donor systems such as carboxylic acids, 1,3-diketonates, hydroxy carboxylic acids, Schiff bases including acyl phenols and iminoacyl groups. As is known, luminescent lanthanide metal complexes require sensitizing group(s) which have the triplet excited energy level higher than the first excited state of the metal ion. Emission is from an f-f transition of the metal and so the emission colour is determined by the choice of the metal. The sharp emission is generally narrow, resulting in a pure colour emission useful for display applications.

The d-block metals are particularly suitable for emission from triplet excited states. These metals form organometallic complexes with carbon or nitrogen donors such as porphyrin or bidentate ligands of formula (IV):

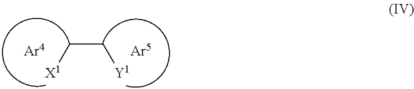

wherein Ar⁴ and Ar⁵ may be the same or different and are independently selected from optionally substituted aryl or heteroaryl; X¹ and Y¹ may be the same or different and are independently selected from carbon or nitrogen; and Ar⁴ and Ar⁵ may be fused together. Ligands wherein X¹ is carbon and Y¹ is nitrogen are particularly preferred.

Examples of bidentate ligands are illustrated below:

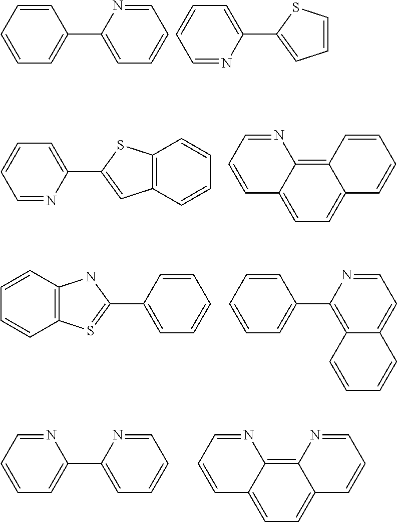

Each of Ar⁴ and Ar⁵ may carry one or more substituents. Two or more of these substituents may be linked to form a ring, for example an aromatic ring. Particularly preferred substituents include fluorine or trifluoromethyl which may be used to blue-shift the emission of the complex as disclosed in WO 02/45466, WO 02/44189, US 2002-117662 and US 2002-182441; alkyl or alkoxy groups as disclosed in JP 2002-324679; carbazole which may be used to assist hole transport to the complex when used as an emissive material as disclosed in WO 02/81448; bromine, chlorine or iodine which can serve to functionalise the ligand for attachment of further groups as disclosed in WO 02/68435 and EP 1245659; and dendrons which may be used to obtain or enhance solution processability of the metal complex as disclosed in WO 02/66552.

A light-emitting dendrimer typically comprises a light-emitting core bound to one or more dendrons, wherein each dendron comprises a branching point and two or more dendritic branches. Preferably, the dendron is at least partially conjugated, and at least one of the core and dendritic branches comprises an aryl or heteroaryl group.

Other ligands suitable for use with d-block elements include diketonates, in particular acetylacetonate (acac); triarylphosphines and pyridine, each of which may be substituted.

Main group metal complexes show ligand based, or charge transfer emission. For these complexes, the emission colour is determined by the choice of ligand as well as the metal.

A wide range of fluorescent low molecular weight metal complexes are known and have been demonstrated in organic light emitting devices [see, e.g., Macromol. Sym. 125 (1997) 1-48, U.S. Pat. No. 5,150,006, U.S. Pat. No. 6,083,634 and U.S. Pat. No. 5,432,014]. Suitable ligands for di or trivalent metals include: oxinoids, e.g. with oxygen-nitrogen or oxygen-oxygen donating atoms, generally a ring nitrogen atom with a substituent oxygen atom, or a substituent nitrogen atom or oxygen atom with a substituent oxygen atom such as 8-hydroxyquinolate and hydroxyquinoxalinol-10-hydroxybenzo (h) quinolinato (II), benzazoles (III), Schiff bases, azoindoles, chromone derivatives, 3-hydroxyflavone, and carboxylic acids such as salicylato amino carboxylates and ester carboxylates. Optional substituents include halogen, alkyl, alkoxy, haloalkyl, cyano, amino, amido, sulfonyl, carbonyl, aryl or heteroaryl on the (hetero) aromatic rings which may modify the emission colour.

The host polymer and the light-emitting dopant may be physically mixed. Alternatively, the light-emitting dopant may be chemically bound to the polymer. The light-emitting dopant may be chemically bound as a substituent attached to the polymer backbone, incorporated as a repeat unit in the polymer backbone or provided as an end-group of the polymer as disclosed in, for example, EP 1245659, WO 02/31896, WO 03/18653 and WO 03/22908.

This binding may result in more efficient transfer of excitons from the host polymer to the light emitting dopant because it may provide intramolecular exciton transfer pathways unavailable to a corresponding mixed system.

Moreover, binding may be beneficial for processing reasons. For example, if the light emitting dopant has low solubility then binding it to a soluble polymer allows the light emitting dopant to be carried in solution by the charge transporting material, enabling device fabrication using solution processing techniques. Furthermore, binding the light emitting dopant to the polymer may prevent phase separation effects in solution-processed devices that may be detrimental to device performance.

More than one light-emitting dopant may be used. For example, red, green and blue light-emitting dopants may be used to obtain white light emission. The polymer of the invention may also emit light, in particular blue light, which may be combined with emission from one or more further dopants to achieve white light.

### Hole Injection Layers

A conductive hole injection layer, which may be formed from a conductive organic or inorganic material, may be provided between the anode 2 and the light-emitting layer 3 to assist hole injection from the anode into the layer or layers of semiconducting polymer. Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx MoOx and RuOx as disclosed in Journal of Physics D: Applied Physics (1996), 29(11), 2750-2753.

### Charge Transporting Layers

A hole transporting layer may be provided between the anode and the light-emitting layer. Likewise, an electron transporting layer may be provided between the cathode and the light-emitting layer.

Similarly, an electron blocking layer may be provided between the anode and the light-emitting layer and a hole blocking layer may be provided between the cathode and the light-emitting layer. Transporting and blocking layers may be used in combination. Depending on its HOMO and LUMO levels, a single layer may both transport one of holes and electrons and block the other of holes and electrons.

If present, a hole transporting layer located between anode 2 and light-emitting layer 3 preferably has a HOMO level of less than or equal to 5.5 eV, more preferably around 4.8-5.5 eV. HOMO levels may be measured by cyclic voltammetry, for example.

If present, an electron transporting layer located between light-emitting layer 3 and cathode 4 preferably has a LUMO level of around 3-3.5 eV. For example, a layer of a silicon monoxide or silicon dioxide or other thin dielectric layer having thickness in the range of 0.2-2 nm is provided between light-emitting layer 3 and layer 4.

A hole transporting layer may contain a polymer comprising hole transporting repeat units of formula (I); likewise, an electron transporting layer may contain a polymer comprising electron transporting repeat units of formula (I).

### Cathode

Cathode 4 is selected from materials that have a workfunction allowing injection of electrons into the light-emitting layer. Other factors influence the selection of the cathode such as the possibility of adverse interactions between the cathode and the light-emitting material. The cathode may consist of a single material such as a layer of aluminium. Alternatively, it may comprise a plurality of metals, for example a bilayer of a low workfunction material and a high workfunction material such as calcium and aluminium as disclosed in WO 98/10621; elemental barium as disclosed in WO 98/57381, Appl. Phys. Lett. 2002, 81(4), 634 and WO 02/84759; or a thin layer of metal compound, in particular an oxide or fluoride of an alkali or alkali earth metal, to assist electron injection, for example lithium fluoride as disclosed in WO 00/48258; barium fluoride as disclosed in Appl. Phys. Lett. 2001, 79(5), 2001; and barium oxide. In order to provide efficient injection of electrons into the device, the cathode preferably has a workfunction of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

### Encapsulation

Organic optoelectronic devices tend to be sensitive to moisture and oxygen. Accordingly, the substrate preferably has good barrier properties for prevention of ingress of moisture and oxygen into the device. The substrate is commonly glass, however alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

The device may be encapsulated with an encapsulant (not shown) to prevent ingress of moisture and oxygen. Suitable encapsulants include a sheet of glass, films having suitable barrier properties such as silicon dioxide, silicon monoxide, silicon nitride or alternating stacks of polymer and dielectric as disclosed in, for example, WO 01/81649 or an airtight container as disclosed in, for example, WO 01/19142. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

### Solution Processing

Suitable solvents for forming compositions of the polymer for solution processing include many common organic solvents, such as mono- or poly-alkylbenzenes such as toluene and xylene.

Particularly preferred solution deposition techniques including printing and coating techniques such spin-coating and inkjet printing.

Spin-coating is particularly suitable for devices wherein patterning of the electroluminescent material is unnecessary—for example for lighting applications or simple monochrome segmented displays.

Inkjet printing is particularly suitable for high information content displays, in particular full colour displays. A device may be inkjet printed by providing a patterned layer over the first electrode and defining wells for printing of one colour (in the case of a monochrome device) or multiple colours (in the case of a multicolour, in particular full colour device). The patterned layer is typically a layer of photoresist that is patterned to define wells as described in, for example, EP 0880303.

As an alternative to wells, the ink may be printed into channels defined within a patterned layer. In particular, the photoresist may be patterned to form channels which, unlike wells, extend over a plurality of pixels and which may be closed or open at the channel ends.

Other solution deposition techniques include dip-coating, roll printing and screen printing.

### EXAMPLES

Polymers comprising a conjugating fluorene repeat unit of formula (IV), a hole transporting amine repeat unit of formula (V) and a non-conjugating repeat unit were prepared by Suzuki polymerisation as described in WO 00/53656.

### Example 1

79% Conjugating repeat unit, 6% hole transporting unit, 15% Conjugation breaker unit

### Example 2

89% Conjugating repeat unit, 6% hole transporting unit, 5% Conjugation breaker unit

### Applications

The polymer may be used as a host material for a fluorescent or phosphorescent light-emitting dopant provided that the singlet excited state energy level (for a fluorescent dopant) or the triplet excited state energy level (for a phosphorescent dopant) is lower than that of the polymer. Preferably, the gap between the host and dopant excited state energy levels is at least kT in order to avoid back transfer of excitons from the dopant to the host material.

The non-conjugating repeat units serve to increase the HOMO-LUMO bandgap of the polymer as compared to a conjugated polymer, thus increasing the range of dopants that the polymer can be used as a host for, without necessitating the use of spacer groups such as alkyl chains that can impart oily or waxy properties to the polymer and make purification of the polymer problematic. Moreover, the cyclic non-conjugating units of the present invention may impart rigidity to the polymer and increase the glass transition temperature of the polymer. The bulk of the cyclic non-conjugating units may also prevent aggregation of polymer chains.

Moreover, the polymers may be used as light-emitting polymers having a colour of emission that is blue-shifted as compared to the corresponding polymer without non-conjugating repeat units.

The polymers may also be used as charge transporting materials, in particular hole transporting materials.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. A light-emitting composition comprising a host polymer and a light emitting dopant wherein the host polymer comprises conjugating repeat units and non-conjugating repeat units in a backbone of the polymer and wherein:
the conjugating repeat units provide at least one conjugation path between repeat units linked thereto; and
the non-conjugating repeat units comprise an at least partially saturated ring having at least one ring atom that breaks any conjugation path between repeat units linked to the non-conjugating repeat unit such that a highest occupied molecular orbital level of the polymer is further from vacuum level by at least 0.1 eV and/or a lowest unoccupied molecular orbital level of the polymer is closer to vacuum level by at least 0.1 eV as compared to a polymer in which the non-conjugating repeat units are absent.

2. A light-emitting composition according to claim 1 wherein the at least one ring atom is a carbon atom.

3. A light-emitting composition according to claim 2 wherein the at least partially saturated ring is carbocyclic.

4. A light-emitting composition according to claim 1 wherein the at least partially saturated ring is fused to at least one further ring.

5. A light-emitting composition according to claim 4 wherein the at least one further ring is an aromatic ring.

6. A light-emitting composition according to claim 4 wherein the at least one further ring is a non-aromatic ring.

7. A light-emitting composition according to claim 6 wherein the non-conjugating repeat unit comprises adamantane.

8. A light-emitting composition according to claim 1 wherein the light-emitting dopant is a fluorescent dopant

9. A light-emitting composition according to claim 1 wherein the light-emitting dopant is a phosphorescent dopant.

10. A light-emitting composition according to claim 1 wherein the light-emitting dopant is blended with the host polymer.

11. A light-emitting composition according to claim 1 wherein the light-emitting dopant is bound to the host polymer.

12. A light-emitting composition according to claim 11 wherein the light-emitting dopant is present in the backbone of the polymer or a sidechain or endgroup of the polymer.

13. A light-emitting composition according to claim 1 wherein the polymer comprises hole-transporting repeat units.

14. A light-emitting composition according to claim 13 wherein the hole-transporting repeat units have formula (V): 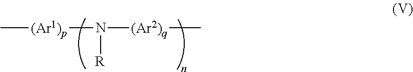
wherein Ar¹ and Ar² in each occurrence are independently selected from optionally substituted aryl or heteroaryl groups, n is greater than or equal to 1, R is H or a substituent, p and q are each independently 1, 2 or 3, and any of the aryl or heteroaryl groups of formula (V) may be linked by a direct bond or a divalent linking group.

15. A light-emitting composition according to claim 1 wherein the polymer comprises electron-transporting repeat units.

16. A light-emitting composition according to claim 15 wherein the electron-transporting repeat units comprise formula (II):
—(Ar¹)ᵣ-Het-(Ar²)ᵣ— (II)
wherein Ar¹ and Ar² in each occurrence are independently selected from optionally substituted aryl or heteroaryl groups; r is at least 1, Het represents an optionally substituted heteroaryl group with high electron affinity, and Ar¹, Ar² and Het independently in each occurrence are optionally substituted.

17. An organic light-emitting device comprising an anode, a cathode and a light-emitting layer between the anode and the cathode, the light-emitting layer comprising a light-emitting composition according to claim 1.

18. A polymer comprising conjugating repeat units, non-conjugating repeat units and amine repeat units in a backbone of the polymer wherein:
the conjugating repeat units provide at least one conjugation path between repeat units linked thereto;
the non-conjugating repeat units comprise an at least partially saturated ring comprising at least one ring atom that breaks any conjugation path between repeat units linked to the non-conjugating repeat unit such that a highest occupied molecular orbital level of the polymer is further from vacuum level by at least 0.1 eV and/or a lowest unoccupied molecular orbital level of the polymer is closer to vacuum level by at least 0.1 eV as compared to a polymer in which the non-conjugating repeat units are absent; and
the amine repeat units comprise repeat units of formula (V): 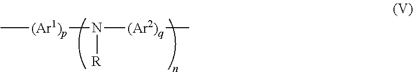
wherein Ar¹ and Ar² in each occurrence are independently selected from optionally substituted aryl or heteroaryl groups, n is greater than or equal to 1, R is H or a substituent, p and q are each independently 1, 2 or 3, and any of the aryl or heteroaryl groups of formula (V) may be linked by a direct bond or a divalent linking group.

19. An organic light-emitting device comprising an anode, a cathode and at least one organic layer including a light-emitting layer between the anode and the cathode, at least one of the organic layers including the polymer according to claim 18.

20. An organic light-emitting device according to claim 19 wherein the polymer is a light-emitting polymer in the light-emitting layer of the device.

21. An organic light-emitting device according to claim 19 wherein one of the organic layers is a hole transporting layer and the polymer is a hole-transporting polymer in the hole transporting layer.

22. (canceled)

23. A method of tuning the bandgap of a polymer comprising conjugating repeat units and non-conjugating repeat units in a backbone of the polymer wherein:
the conjugating repeat units provide at least one conjugation path between repeat units linked thereto; and
the non-conjugating repeat units comprise an at least partially saturated ring having ring atoms that break any conjugation path between repeat units linked to the non-conjugating repeat unit,
the method comprising the step of determining a minimum target bandgap of the polymer that is at least 0.1 eV larger than the bandgap of a polymer in which the non-conjugating repeat units are absent, and polymerising a polymerisation mixture comprising a first monomer comprising a non-conjugating unit and a second monomer comprising a conjugating unit, the ratio of the first and second monomers being selected so as to form a polymer having the minimum target bandgap.

24. A light-emitting composition comprising a host polymer and a light emitting dopant wherein the host polymer comprises conjugating repeat units and non-conjugating repeat units in a backbone of the polymer and wherein:
the conjugating repeat units provide at least one conjugation path between repeat units linked thereto; and
the non-conjugating repeat units comprise an at least partially saturated ring having ring atoms that break any conjugation path between repeat units linked to the non-conjugating repeat unit, at least one of said ring atoms being a carbon atom.

25. A light-emitting composition according to claim 2 wherein the at least partially saturated ring is a cycloalkane.

26. A light-emitting composition according to claim 14 wherein n is 1 or 2 and R is a substituent.

27. A light-emitting composition according to claim 16 wherein r is 1-3.
